(19) United States
(12) Patent Application Publication
(10) Pub. No.: US 2015/0160306 A1
(43) Pub. Date: Jun. 11, 2015

(54) ORTHOGONAL FLUXGATE SENSOR

(71) Applicant: SAMSUNG ELECTRO-MECHANICS CO., LTD., Suwon-Si (KR)

(72) Inventors: Dae Ho Kim, Suwon-Si (KR); Eun Tae Park, Suwon-Si (KR)

(73) Assignee: SAMSUNG ELECTRO-MECHANICS CO., LTD., Suwon-Si (KR)

(21) Appl. No.: 14/218,329

(22) Filed: Mar. 18, 2014

(30) Foreign Application Priority Data
Dec. 9, 2013 (KR) 10-2013-0152370

(51) Int. Cl. G01R 33/04; G01R 33/00

(52) U.S. Cl. CPC G01R 33/04; G01R 33/0005

(57) ABSTRACT

There is provided an orthogonal fluxgate sensor including: a magnetic core unit having a lattice structure; first and second coils enclosing the magnetic core unit in a solenoid form; and a third coil surrounding the magnetic core unit and the first and second coils, wherein the first and second coils are disposed to be perpendicular to one another, and when an alternating current (AC) power source is connected to at least one of the first and second coils, an AC voltmeter is connected to the third coil, and when the AC power source is connected to the third coil, the AC voltmeter is connected to at least one of the first and second coils.

### CROSS-REFERENCE TO RELATED APPLICATION

This application claims the benefit of Korean Patent Application No. 10-2013-0152370 filed on Dec. 9, 2013, with the Korean Intellectual Property Office, the disclosure of which is incorporated herein by reference.

### BACKGROUND

The present disclosure relates to an orthogonal fluxgate sensor.

A fluxgate sensor is a type of magnetic field sensor measuring a magnitude of a relatively weak external magnetic field by utilizing large permeability of a ferromagnetic material that is easily saturated in a magnetic field.

A fluxgate sensor has been extensively utilized as a sensor for precisely measuring a geo-magnetic field in spaceship and artificial satellites to measure a magnetic field in celestial bodies and space.

In addition, a fluxgate sensor may also be used as an electronic compass of portable electronic devices such as a smartphone, a navigation device, and the like.

An electronic compass of portable electronic devices senses a geo-magnetic field and provides information regarding a direction of a smartphone, a navigation device, and the like, providing a method of overcoming shortcomings of a global positioning system (GPS)-based location tracking.

Currently, a magnetoresistive (MR) sensor, a magnetoimage (MI) sensor, a resonator sensor based on Lorentz force, and a hall sensor, implementing low-cost production and low-power driving while satisfying demand for precision and resolution, are typical geomagnetic sensors applied to electronic compasses of most portable electronic devices.

Current development of such sensors are directed toward improvement of more precise resolution and effective initialization performance to meet new demand for augmented reality, game controllers, indoor navigation devices, and the like, in line with the development of increasingly diversified applications.

A fluxgate sensor supports excellent resolution and effective initialization performance, and thus, if such a fluxgate sensor is miniaturized and driven with low power, it may be widely utilized in portable electronic devices, and the like.

### SUMMARY

An aspect of the present disclosure may provide an orthogonal fluxgate sensor significantly reduced in size and measuring magnetic fields in 3-axis directions.

An aspect of the present disclosure may also provide a compact orthogonal fluxgate sensor having a simpler structure in which three coils alternately serve as a magnetic field generating coil and a detecting coil.

According to a first aspect of the present disclosure, an orthogonal fluxgate sensor may include: a magnetic core unit having a lattice structure; first and second coils enclosing the magnetic core unit in a solenoid form; and a third coil surrounding the magnetic core unit and the first and second coils, wherein the first and second coils are disposed to be perpendicular to one another, and when an alternating current (AC) power source is connected to at least one of the first and second coils, an AC voltmeter is connected to the third coil, and when the AC power source is connected to the third coil, the AC voltmeter is connected to at least one of the first and second coils.

The magnetic core unit may be formed by disposing a plurality of bar-shaped magnetic cores to intersect each other.

The magnetic core unit may include a first magnetic core unit including a plurality of first bar-shaped magnetic cores disposed to be parallel to one another and a second magnetic core unit including a plurality of second bar-shaped magnetic cores disposed to be parallel to one another, and the first and second magnetic core units may be disposed to be perpendicular to one another.

Each of the first magnetic cores provided in the first magnetic core unit may be formed to be narrow in a width direction thereof, relative to length and height directions thereof, and each of the second magnetic cores provided in the second magnetic core unit may be formed to be narrow in a width direction thereof, relative to length and height directions thereof.

Each of the first and second magnetic cores may have lower demagnetizing field over magnetic fields in the length and height directions thereof than those over a magnetic field in the width direction thereof.

The third coil may surround the magnetic core unit and the first and second coils at least once in a spiral manner.

According to a second aspect of the present disclosure, an orthogonal fluxgate sensor may include: a magnetic core unit having a lattice structure; a first coil disposed above the magnetic core unit and having a spiral shape with the parts of the first coil directly above the magnetic core unit forming parallel lines; a second coil disposed below the magnetic core unit and having a spiral shape with the parts of the second coil directly below the magnetic core unit forming parallel lines; and a third coil surrounding the magnetic core unit and the first and second coils, wherein the first and second coils are disposed to be perpendicular to one another, and when an alternating current (AC) power source is connected to at least one of the first and second coils, an AC voltmeter is connected to the third coil, and when the AC power source is connected to the third coil, the AC voltmeter is connected to at least one of the first and second coils.

The magnetic core unit may be formed by disposing a plurality of bar-shaped magnetic cores such that they intersect.

The magnetic core unit may include a first magnetic core unit including a plurality of first bar-shaped magnetic cores disposed to be parallel to one another and a second magnetic core unit including a plurality of second bar-shaped magnetic cores disposed to be parallel to one another, and the first and second magnetic core units are disposed to be perpendicular to one another.

Each of the first magnetic cores provided in the first magnetic core unit may be formed to be narrow in a width direction thereof, relative to length and height directions thereof, and each of the second magnetic cores provided in the second magnetic core unit may be formed to be narrow in a width direction thereof, relative to length and height directions thereof.

Each of the first and second magnetic cores may have lower demagnetizing field over magnetic fields in the length and height directions thereof than those over a magnetic field in the width direction thereof.

The magnetic core unit may be positioned within a region of the first coil in which a current flows in one direction and within a region of the second coil in which a current flows in another direction.

According to a third aspect of the present disclosure, an orthogonal fluxgate sensor may include: a first substrate including a magnetic core unit having a lattice structure formed therein; second and third substrates stacked above and below the first substrate, respectively, and having a second coil surrounding the magnetic core unit in a solenoid form; and fourth and fifth substrates stacked above the second substrate and below the third substrate, respectively, and having a first coil surrounding the magnetic core unit in a solenoid form, wherein the first and second coils are perpendicular to one another, a third coil is formed to surround the magnetic core unit and the first and second coils in at least one of the first to fifth substrates, and when an alternating current (AC) power source is connected to at least one of the first and second coils, an AC voltmeter is connected to the third coil, and when the AC power source is connected to the third coil, the AC voltmeter is connected to at least one of the first and second coils.

The first substrate may include a plurality of first through holes and a plurality of second through holes penetrating therethrough in a rectangular shape, the plurality of first through holes and the plurality of second through holes may be perpendicular to one another, and a plurality of first and second magnetic thin films may be provided on inner walls of the first and second through holes to form the magnetic core unit.

The first and second magnetic thin films provided on the inner walls of the first and second through holes may have lower demagnetizing field over magnetic fields in length and height directions than those over a magnetic field in a width direction thereof.

The second and third substrates may have conductive patterns formed therein, and the first through third substrates may have second via holes to allow end portions of the respective conductive patters to be connected therethrough to form the second coil in a solenoid form.

The fourth and fifth substrates may have conductive patterns formed therein, and the first through fifth substrates may have first via holes to allow end portions of the respective conductive patters to be connected therethrough to form the first coil in a solenoid form.

According to a fourth aspect of the present disclosure, an orthogonal fluxgate sensor may include: a first substrate including a magnetic core unit having a lattice structure formed therein; a second substrate stacked above the first substrate and having a first coil patterned in a spiral shape such that the parts of the first coil directly above the magnetic core unit form parallel lines; a third substrate stacked below the first substrate and having a second coil patterned in a spiral shape such that the parts of the second coil directly below the magnetic core unit form parallel lines; and a fourth substrate stacked above the second substrate or below the third substrate and having a third coil patterned to surround the first and second coils, wherein the first and second coils are perpendicular to one another, and when an alternating current (AC) power source is connected to at least one of the first and second coils, an AC voltmeter is connected to the third coil, and when an AC power source is connected to the third coil, the AC voltmeter is connected to at least one of the first and second coils.

The first substrate may include a plurality of first through holes and a plurality of second through holes penetrating therethrough in a rectangular shape, the plurality of first through holes and the plurality of second through holes are perpendicular to one another, and a plurality of first and second magnetic thin films are provided on inner walls of the first and second through holes to form the magnetic core unit.

The first and second magnetic thin films provided on the inner walls of the first and second through holes may have lower demagnetizing field over magnetic fields in length and height directions than those over a magnetic field in a width direction thereof.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating an orthogonal fluxgate sensor according to a first exemplary embodiment of the present disclosure;

FIG. 2 is a perspective view schematically illustrating an orthogonal fluxgate sensor according to a second exemplary embodiment of the present disclosure;

FIGS. 3A and 3B are plan views illustrating a position of a magnetic core unit in the orthogonal fluxgate sensor according to the second exemplary embodiment of the present disclosure;

FIG. 4A is an exploded perspective view schematically illustrating an orthogonal fluxgate sensor according to a third exemplary embodiment of the present disclosure;

FIG. 4B is a perspective view of a magnetic core unit provided in the orthogonal fluxgate sensor according to the third exemplary embodiment of the present disclosure;

FIG. 5A is an exploded perspective view schematically illustrating an orthogonal fluxgate sensor according to a fourth exemplary embodiment of the present disclosure;

FIG. 5B is a perspective view of a magnetic core unit provided in the orthogonal fluxgate sensor according to the fourth exemplary embodiment of the present disclosure;

FIG. 6A is a perspective view of modified examples of a first substrate and the magnetic core unit provided in the orthogonal fluxgate sensors according to the third and fourth exemplary embodiments of the present disclosure; and

FIG. 6B is a perspective view of a modified example of the magnetic core unit provided in the orthogonal fluxgate sensors according to the third and fourth exemplary embodiments of the present disclosure.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

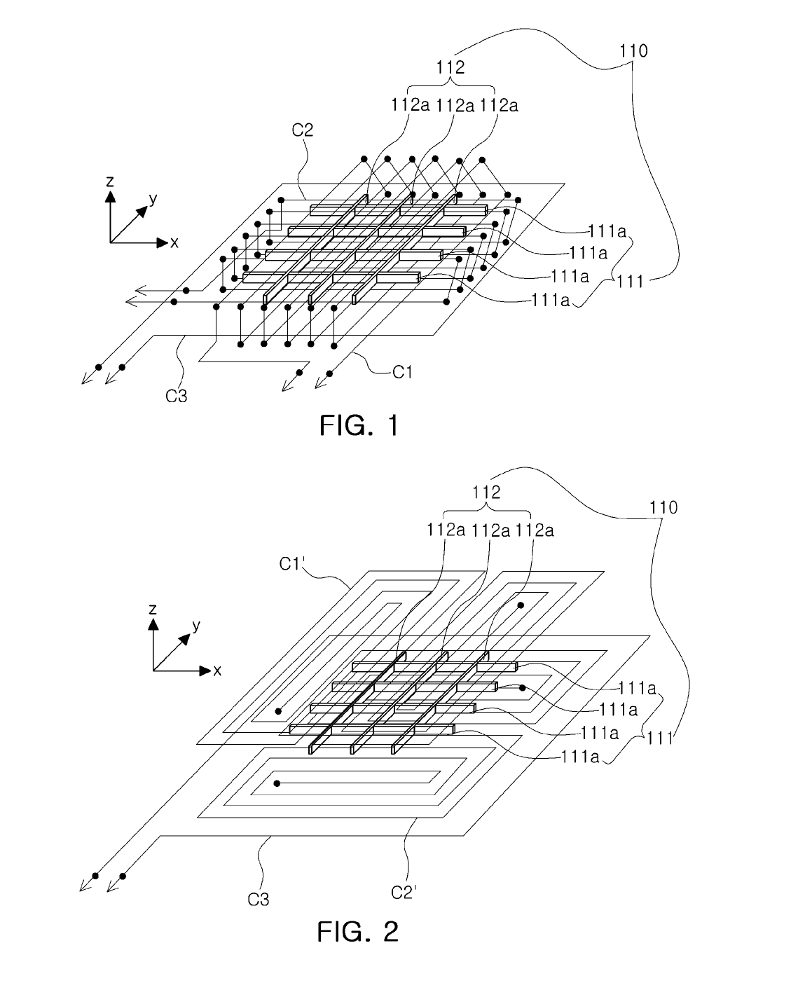

FIG. 1 is a perspective view schematically illustrating an orthogonal fluxgate sensor according to a first exemplary embodiment of the present disclosure.

Referring to FIG. 1, an orthogonal fluxgate sensor according to the first exemplary embodiment of the present disclosure may include a magnetic core unit 110, first and second coils C1 and C2 enclosing the magnetic core unit 110 in a solenoid form, and a third coil C3 surrounding the magnetic core unit 110 and the first and second coils C1 and C2.

The magnetic core unit 110 may have a lattice structure in which a plurality of bar-shaped first magnetic cores 111a and a plurality of bar-shaped second magnetic cores 112a intersect.

For example, the magnetic core unit 110 may include a first magnetic core unit 111 in which a plurality of bar-shaped first magnetic cores 111a are disposed in parallel and a second magnetic core unit 112 in which a plurality of bar-shaped second magnetic cores 112a are disposed in parallel.

The first magnetic core unit 111 and the second magnetic core unit 112 may be disposed to be orthogonal.

Accordingly, the magnetic core unit 110 having a lattice structure may be formed by the first magnetic core unit 111 and the second magnetic core unit 112.

Each of the first and second magnetic cores 111a and 112a may be soft magnets having small residual magnetization and high permeability, and may be formed of spinel-type ferrite, an amorphous alloy, and the like.

The first and second magnetic cores 111a and 112a may be magnetized when an external magnetic field is applied thereto, and may be demagnetized when the applied external magnetic field is removed.

Each of the first and second magnetic cores 111a and 112a may have a narrow, elongated bar shape erected vertically.

For example, each of the first magnetic cores 111a constituting the first magnetic core unit 111 may be formed to be narrower in a width direction (y-axis direction) thereof than in a length direction (x-axis direction) and a height direction (z-axis direction) thereof.

Thus, each of the first magnetic cores 111a constituting the first magnetic core unit 111 may have lower demagnetizing field over magnetic fields in the length direction (x-axis direction) and the height direction (z-axis direction) than those over a magnetic field in the width direction (y-axis direction).

Each of the first magnetic cores 111a constituting the first magnetic core unit 111 may be readily magnetized by the magnetic field in the x-axis direction induced by the first coil C1 or the magnetic field in the z-axis direction induced by the third coil C3.

Meanwhile, each of the second magnetic cores 112a constituting the second magnetic core unit 112 may be formed to be narrower in the width direction (x-axis direction) thereof than in the length direction (y-axis direction) and the height direction (z-axis direction) thereof.

Thus, each of the second magnetic cores 112a constituting the second magnetic core unit 112 may have lower demagnetizing field over magnetic fields in the length direction (y-axis direction) and the height direction (z-axis direction) than those over the magnetic field in the width direction (x-axis direction).

Each of the second magnetic cores 112a constituting the second magnetic core unit 112 may be readily magnetized by the magnetic field in the y-axis direction induced by the second coil C2 and the magnetic field in the z-axis direction induced by the third coil C3.

The first coil C1 and the second coil C2 may be provided to enclose the magnetic core unit 110 in a solenoid form, and may be disposed to be orthogonal to one another.

The third coil C3 may be provided to surround the magnetic core unit 110 and the first and second coils C1 and C2.

In detail, the third coil C3 may surround the first magnetic core unit 110 and the first and second coils C1 and C2 on a plane (x-y plane) on which the magnetic core unit 110 is formed.

Also, the third coil C3 may surround the magnetic core unit 110 and the first and second coils C1 and C2 on the x-y plane at least once in a spiral manner.

The first, second, and third coils C1, C2, and C3 may be magnetic field generating coils generating a magnetic field to magnetize the magnetic core unit 110 upon receiving an alternating current (AC) applied thereto, or may be detecting coils measuring an induction voltage due to a change in magnetic moment of the magnetic core unit 110 caused by an external magnetic field.

Namely, in the orthogonal fluxgate sensor according to the first exemplary embodiment, when the first or second coil C1 or C2 serves as a magnetic field generating coil, the third coil C3 may serve as a detecting coil, and when the third coil C3 serves as a magnetic field generating coil, the first or second coil C1 or C2 may serve as a detecting coil.

To this end, in a case in which an AC power source is connected to the first or second coil C1 or C2, an AC voltmeter may be connected to the third coil C3, and in a case in which the AC power source is connected to the third coil C3, the AC voltmeter may be connected to the first or second coil C1 or C2.

Thus, the first to third coils C1 to C3 may alternately serve to generate a magnetic field and detect a change in magnetic flux.

For example, in a case in which AC is applied to the first or second coil C1 or C2 to generate a magnetic field, a voltage induced to the third coil C3 due to a change in magnetic moment of the magnetic core unit 110 may be measured, and in a case in which AC is applied to the third coil C3 to generate a magnetic field, a voltage induced to the first or second coil C1 or C2 due to a change in magnetic moment of the magnetic core unit 110 may be measured.

The orthogonal fluxgate sensor according to the first exemplary embodiment of the present disclosure may operate as follows.

A method of measuring an external magnetic field (geo-magnetic field) in the z-axis direction will be described with reference to FIG. 1.

When an external magnetic field in the z-axis direction is applied, the first magnetic core unit 111 has magnetic moment proportional to the external magnetic field in the z-axis direction.

Here, a current is applied to the first coil C1 to apply a magnetic field in the x-axis direction to the first magnetic core unit 111.

Namely, in the orthogonal fluxgate sensor according to the first exemplary embodiment of the present disclosure, the direction (here, the z-axis direction) of the external magnetic field intended to be measured and the direction (here, the x-axis direction) of the magnetic field generated by the magnetic field generating coil (here, the first coil C1) to magnetize the first magnetic core unit 111 form a right angle.

The current applied to the first coil C1 is an AC, so the direction of the magnetic field thereof is repeatedly changing between a positive (+) direction and a negative (−) direction of the x-axis.

When an instantaneous current value of the AC applied to the first coil C1 is 0, the magnetic moment of the first magnetic core unit 111 is maintained at the initial value (with its component only along the z-axis).

When the instantaneous current value of the AC applied to the first coil C1 has a maximum positive value, the magnetic moment of the first magnetic core unit 111 is saturated to the x-axis direction, and thus, the initial component along the z-axis is rapidly reduced.

Here, the component along the z-axis of the magnetic moment of the first magnetic core unit 111 is changed, and a change in magnetic flux corresponding thereto may be sensed by the third coil C3.

Each time the instantaneous current value of the AC applied to the first coil C1 is changing between 0 and the maximum value thereof, the magnetic moment of the first magnetic core unit 111 in the z-axis direction is changed and may be measured by the voltage induced to the third coil C3.

The measured voltage of the third coil C3 is proportional to the magnitude of the external magnetic field in the z-axis direction.

Namely, the external magnetic field in the z-axis direction may be detected by measuring the voltage induced to the third coil C3.

Here, the first coil C1 to which the AC power source is connected may serve as a magnetic field generating coil, and the third coil C3 connected to the AC voltmeter may serve as a detecting coil.

Meanwhile, when the external magnetic field (geo-magnetic field) in the z-axis direction is measured, the second coil C2 may serve as a magnetic field generating coil.

For example, the voltage induced to the third coil C3 may also be measured by applying an AC to the second coil C2 to generate a magnetic field in the y-axis direction, thus saturating the magnetic moment of the second magnetic core unit 112 in the y-axis direction.

In this case, the second coil C2 to which the AC power source is connected may serve as a magnetic field generating coil and the third coil C3 connected to the AC voltmeter may serve as a detecting coil.

Also, after an AC is simultaneously applied to both the first coil C1 and the second coil C2, the external magnetic field (geo-magnetic field) in the z-axis direction may be measured by using both the first and second magnetic core units 111 and 112.

Thus, in measuring the external magnetic field (geo-magnetic field) in the z-axis direction, at least one of the first and second coils C1 and C2 may serve as a magnetic field generating coil and the third coil C3 may serve as a detecting coil.

To this end, the AC power source may be connected to at least one of the first and second coils C1 and C2, and the third coil C3 may be connected to the AC voltmeter.

Hereinafter, a method of measuring an external magnetic field (geo-magnetic field) in the x-axis direction will be described.

When an external magnetic field in the x-axis direction is applied, the first magnetic core unit 111 has magnetic moment proportional to the external magnetic field in the x-axis direction.

Here, a current is applied to the third coil C3 to apply a magnetic field in the z-axis direction to the first magnetic core unit 111.

Namely, in the orthogonal fluxgate sensor according to the first exemplary embodiment of the present disclosure, the direction (here, the x-axis direction) of the external magnetic field intended to be measured and the direction (here, the z-axis direction) of the magnetic field generated by the magnetic field generating coil (here, the third coil C3) to magnetize the first magnetic core unit 111 form a right angle.

The current applied to the third coil C3 is an AC, so the direction of the magnetic field thereof is repeatedly changing between a positive (+) direction and a negative (−) direction of the z-axis.

When an instantaneous current value of the AC applied to the third coil C3 is 0, the magnetic moment of the first magnetic core unit 111 is maintained at the initial value (with its component only along the x-axis).

When the instantaneous current value of the AC applied to the third coil C3 has a maximum positive value, the magnetic moment of the first magnetic core unit 111 is saturated to the z-axis direction, and thus, the initial component along the z-axis is rapidly reduced.

Here, the component along the x-axis of the magnetic moment of the first magnetic core unit 111 is changed, and a change in magnetic flux corresponding thereto may be sensed by the first coil C1.

Each time the instantaneous current value of the AC applied to the third coil C3 is changing between 0 and the maximum value thereof, the magnetic moment of the first magnetic core unit 111 in the x-axis direction is changed and may be measured by the voltage induced to the first coil C1.

The measured voltage of the first coil C1 is proportional to the magnitude of the external magnetic field in the x-axis direction.

Namely, the external magnetic field in the x-axis direction may be detected by measuring the voltage induced to the first coil C1.

Here, the third coil C3 to which the AC power source is connected may serve as a magnetic field generating coil, and the first coil C1 connected to the AC voltmeter may serve as a detecting coil.

Hereinafter, a method of measuring an external magnetic field (geo-magnetic field) in the y-axis direction will be described.

When an external magnetic field in the y-axis direction is applied, the second magnetic core unit 112 has magnetic moment proportional to the external magnetic field in the y-axis direction.

Here, a current is applied to the third coil C3 to apply a magnetic field in the z-axis direction to the second magnetic core unit 112.

Namely, in the orthogonal fluxgate sensor according to the first exemplary embodiment of the present disclosure, the direction (here, the y-axis direction) of the external magnetic field intended to be measured and the direction (here, the z-axis direction) of the magnetic field generated by the magnetic field generating coil (here, the third coil C3) to magnetize the second magnetic core unit 112 form a right angle.

The current applied to the third coil C3 is an AC, so the direction of the magnetic field thereof is repeatedly changing between a positive (+) direction and a negative (−) direction of the z axis.

When an instantaneous current value of the AC applied to the third coil C3 is 0, the magnetic moment of the second magnetic core unit 112 is maintained at the initial value (with its component only along the y-axis).

When the instantaneous current value of the AC applied to the third coil C3 has a maximum positive value, the magnetic moment of the second magnetic core unit 112 is saturated to the z-axis direction, and thus, the initial component along the y-axis is rapidly reduced.

Here, the component along the y-axis of the magnetic moment of the second magnetic core unit 112 is changed, and a change in magnetic flux corresponding thereto may be sensed by the second coil C2.

Each time the instantaneous current value of the AC applied to the first coil C1 is changing between 0 and the maximum value thereof, the magnetic moment of the second magnetic core unit 112 in the y-axis direction is changed and may be measured by the voltage induced to the second coil C2.

The measured voltage of the second coil C2 is proportional to the magnitude of the external magnetic field in the y-axis direction.

Namely, the external magnetic field in the y-axis direction may be detected by measuring the voltage induced to the second coil C2.

Here, the third coil C3 to which the AC power source is connected may serve as a magnetic field generating coil, and the second coil C2 connected to the AC voltmeter may serve as a detecting coil.

In the orthogonal fluxgate sensor according to the first exemplary embodiment of the present disclosure, since the first to third coils C1 to C3 may alternately serve as a magnetic field generating coil and a detecting coil, eliminating the need for a separate magnetic field generating coil and a detecting coil, the overall size of the sensor may be reduced.

Also, since the plurality of magnetic cores 111a and 112a orthogonally disposed have a width smaller than a length and a height thereof, demagnetizing field of the magnetic core units 110 with respect to the magnetic fields in the length direction (the x-axis direction or the y-axis direction) and the height direction (the z-axis direction or the direction perpendicular to the x-y plane) may be reduced, improving sensitivity and efficiency of the sensor.

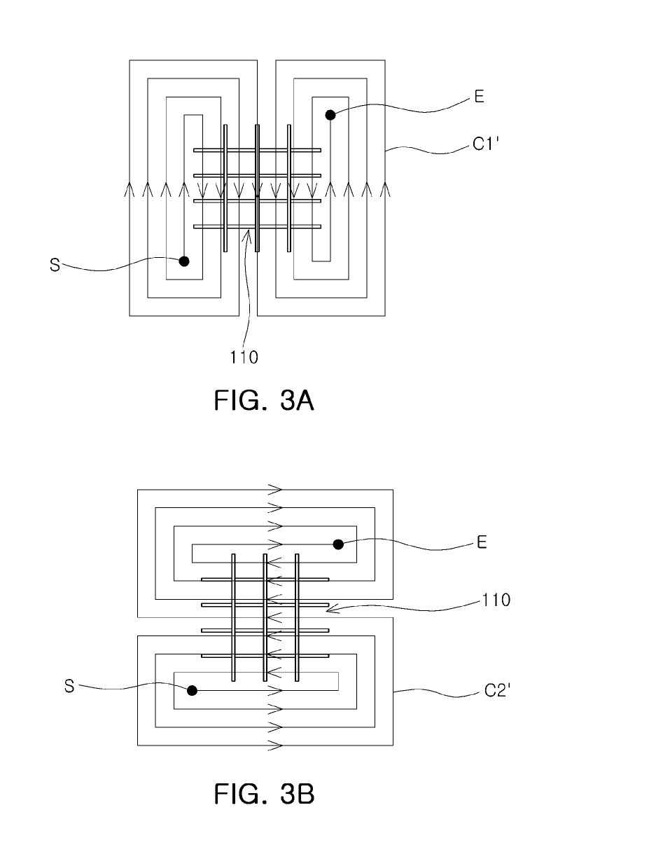

FIG. 2 is a perspective view schematically illustrating an orthogonal fluxgate sensor according to a second exemplary embodiment of the present disclosure, and FIGS. 3A and 3B are plan views illustrating a position of a magnetic core unit in the orthogonal fluxgate sensor according to the second exemplary embodiment of the present disclosure.

Referring to FIG. 2, the orthogonal fluxgate sensor according to the second exemplary embodiment of the present disclosure is identical to the orthogonal fluxgate sensor according to the first exemplary embodiment of the present disclosure as described above, except for first and second coils C1′ and C2′. Thus, descriptions thereof, excluding those of the first and second coils C1′ and C2′, will be omitted.

The first coil C1′ may be disposed above the magnetic core unit 110, and the second coil C2′ may be disposed below the magnetic core unit 110.

The first and second coils C1′ and C2′ may have a spiral shape with the parts of the first and second coils C1′ and C2′ directly above or below the magnetic core unit 110 forming parallel lines, and may be disposed to be perpendicular to one another.

The first coil C1′ may be formed by connecting the outermost coil strands of two coils wound in the same direction.

Also, the first coil C1′ may be formed to spread, while being wound in one direction, and be rewound in the opposite direction.

In other words, the first coil C1′ may have a dual-spiral structure.

Since the first coil C1′ may have a dual spiral structure, when a current is applied to the first coil C1′, the current flows in the same direction in an inner portion of the first coil C1′.

For example, referring to FIG. 3A, when it is assumed that a current flows from a start point S to an end point E of the first coil C1′, the current flows in the arrow direction illustrated in FIG. 3A, and in a portion (namely, an inner portion of the first coil C1′) between the start point S and the end point E, the current flows in the same direction.

Also, referring to FIG. 3B, a current flows in the arrow direction illustrated in FIG. 3B in the second coil C2′, and in a portion (namely, an inner portion of the second coil C2′) between a start point S and an end point E of the second coil C2′, the current flows in the same direction.

Here, the magnetic core unit 110 may be positioned within the region of the first coil C1′ in which the current flows in one direction and the region of the second coil C2′ in which the current flows in another direction.

Also, the magnetic core unit 110 may be positioned between the start points S and the end points E of the first and second coils C1′ and C2′.

Thus, a magnetic field may be applied to the entirety of the magnetic core unit 110 in a predetermined direction by the first and second coils C1′ and C2′.

Meanwhile, a third coil C3 may be provided to surround the magnetic core unit 110 and the first and second coils C1′ and C2′.

In detail, the third coil C3 may surround the magnetic core unit 110 and the first and second coils C1′ and C2′ on the plane (x-y plane) on which the magnetic core unit 110 is formed.

Further, the third coil C3 may surround the magnetic core unit 110 and the first and second coils C1′ and C2′ at least once in a spiral manner on the x-y plane.

The orthogonal fluxgate sensor according to the second exemplary embodiment of the present disclosure may operate in the same manner as that of the orthogonal fluxgate sensor according to the first exemplary embodiment of the present disclosure.

For example, in case of measuring an external magnetic field (geo-magnetic field) in the z-axis direction, magnetic moment of the first magnetic core unit 111 may be saturated in the x-axis direction by generating a magnetic field in the x-axis direction by applying an AC current to the first coil C1′. Here, an external magnetic field in the z-axis direction may be detected by measuring a voltage induced to the third coil C3.

Also, magnetic moment of the second magnetic core unit 112 may be saturated in the y-axis direction by generating a magnetic field in the y-axis direction by applying an AC current to the second coil C2′. Here, an external magnetic field in the z-axis direction may be detected by measuring a voltage induced to the third coil C3.

Meanwhile, after an AC current source is simultaneously connected to both the first and second coils C1′ and C2′, the external magnetic field (geo-magnetic field) may be measured by using both the first and second magnetic core units 111 and 112.

Thus, in measuring the external magnetic field (geo-magnetic field) in the z-axis direction, at least one of the first and second coils C1′ and C2′ may serve as a magnetic field generating coil and the third coil C3′ may serve as a detecting coil.

The foregoing descriptions of the orthogonal fluxgate sensor according to the first exemplary embodiment of the present disclosure will be used for the method of measuring the external magnetic fields (geo-magnetic fields) in the x-axis and y-axis directions.

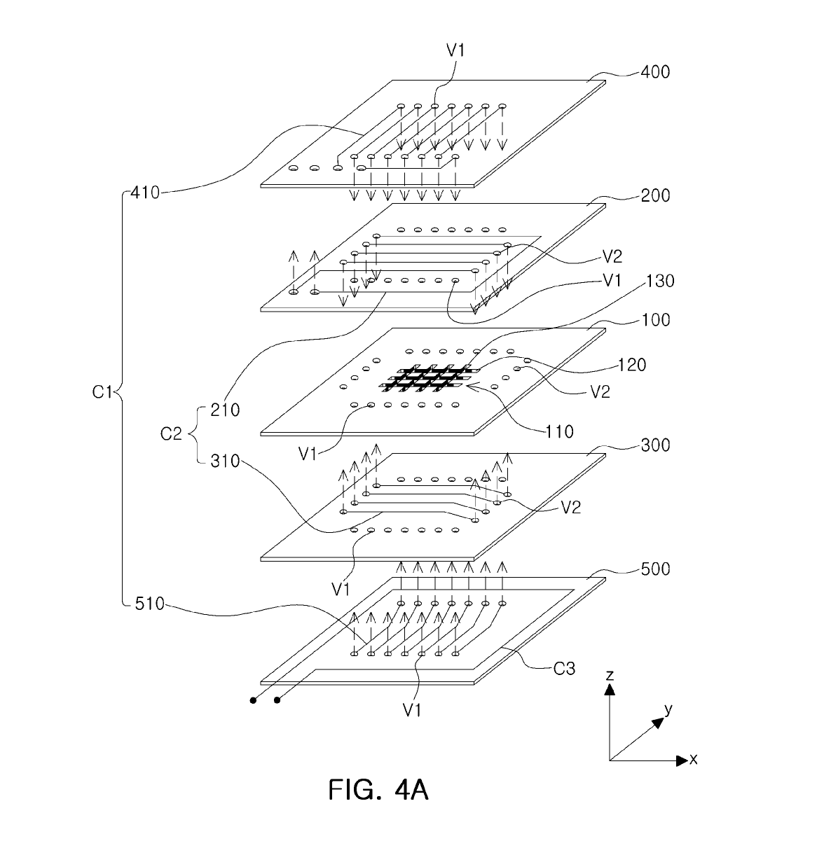

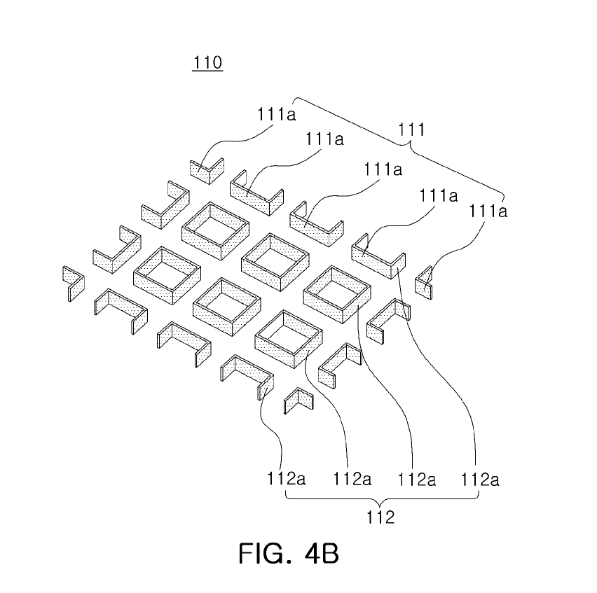

FIG. 4A is an exploded perspective view schematically illustrating an orthogonal fluxgate sensor according to a third exemplary embodiment of the present disclosure, and FIG. 4B is a perspective view of a magnetic core unit provided in the orthogonal fluxgate sensor according to the third exemplary embodiment of the present disclosure.

Referring to FIG. 4A, the orthogonal fluxgate sensor according to the third exemplary embodiment of the present disclosure may include a first substrate 100 in which a magnetic core unit 110 is formed, and second, third, fourth, and fifth substrates 200, 300, 400, and 500 in which conductive patterns 210, 310, 410, and 510 are formed, respectively.

The second to fifth substrates 200 to 500 may be respectively stacked above and below the first substrate 100 with the first substrate 100 as a center, forming a multi-layer substrate.

The magnetic core unit 110 having a lattice structure may be formed in the first substrate 100.

A plurality of first through holes 120 having a rectangular shape may be formed in the first substrate 100 such that they penetrate through the first substrate 100, and in this case, the first through holes 120 may be formed to be parallel to one another.

Also, a plurality of through holes 130 may be formed to be perpendicular to the plurality of first through holes 120 in the first substrate 100, and in this case, the second through holes may be formed to be parallel to one another.

Through holes having a lattice structure may be formed by the plurality of first through holes 120 and the plurality of second through holes 130 in the first substrate 100.

Referring to FIG. 4B, a plurality of first and second magnetic thin films 111a and 112a may be provided on inner walls of the first and second through holes 120 and 130, forming the magnetic core unit 110.

For example, a first magnetic core unit 111 may be formed by the plurality of first magnetic thin films 111a provided on the inner walls of the first through holes 120, and a second magnetic core unit 112 may be formed by the plurality of second magnetic thin films 112a provided on the inner walls of the second through holes 130.

The magnetic core unit 110 having the lattice structure may be formed by the first and second magnetic core units 111 and 112 in the first substrate 100.

The magnetic core unit 110 may be formed by depositing the first and second magnetic thin films 111a and 112a on the inner walls of the first and second through holes 120 and 130 by utilizing a thin film deposition method such as physical vapor deposition, chemical deposition, electro-deposition, and the like.

The magnetic core unit 110 may be a soft magnet having small residual magnetization and high permeability, and may be formed of spinel-type ferrite, an amorphous alloy, and the like.

The magnetic core unit 110 may be magnetized when an external magnetic field is applied thereto, and demagnetized when the applied external magnetic field is removed.

Each of the first and second magnetic thin films 111a and 112a may have a narrow, elongated bar shape erected vertically.

For example, each of the first magnetic thin films 111a constituting the first magnetic core unit 111 may be formed to be narrower in a width direction (y-axis direction) thereof than in a length direction (x-axis direction) and a height direction (z-axis direction) thereof.

Thus, each of the first magnetic thin films 111a constituting the first magnetic core unit 111 may have lower demagnetizing field over magnetic fields in the length direction (x-axis direction) thereof and the height direction (z-axis direction) than those over the magnetic field in the width direction (y-axis direction) thereof.

Each of the first magnetic thin films 111a constituting the first magnetic core unit 111 may be readily magnetized by the magnetic field in the x-axis direction induced by the first coil C1 and the magnetic field in the z-axis direction inducted by the third coil C3.

Meanwhile, each of the second magnetic thin films 112a constituting the second magnetic core unit 112 may be formed to be narrower in the width direction (x-axis direction) thereof than in the length direction (y-axis direction) and the height direction (z-axis direction) thereof.

Thus, each of the second magnetic thin films 112a constituting the second magnetic core unit 112 may have lower demagnetizing field over magnetic fields in the length direction (y-axis direction) and the height direction (z-axis direction) than those over the magnetic field in the width direction (x-axis direction).

Each of the second magnetic thin films 112a constituting the second magnetic core unit 112 may be readily magnetized by the magnetic field in the y-axis direction induced by the second coil C2 and the magnetic field in the z-axis direction induced by the third coil C3.

The second substrate 200 may be stacked on the first substrate 100 and the third substrate 300 may be stacked below the first substrate 100.

Conductive patterns 210 and 310 may be formed in the second and third substrates 200 and 300, respectively, and the each of the conductive patterns 210 and 310 may be electrically connected by second via holes V2 formed in the first to third substrate 100 to 300.

End portions of the conductive patterns 210 and 310 formed in the second and third substrates 200 and 300, respectively, may be connected by the second via holes V2 to enclose the magnetic core unit 110 in a solenoid form.

For example, the conductive patterns 210 and 310 formed in the second and third substrates 200 and 300, respectively, may be connected by the second via holes V2 to configure the second coil C2 enclosing the magnetic core unit 110 in a solenoid form.

The fourth substrate 400 may be stacked on the second substrate 200, and the fifth substrate 500 may be stacked below the third substrate 300.

Conductive patterns 410 and 510 may be formed on the fourth and fifth substrates 400 and 500, respectively, and the respective conductive patterns 410 and 510 may be electrically connected by first via holes V1 formed in the first to fifth substrates 100 to 500.

End portions of the conductive patterns 410 and 510 formed in the fourth and fifth substrates 400 and 500, respectively, may be connected by the first via holes V1 to enclose the magnetic core unit 110 in a solenoid form.

For example, the conductive patterns 410 and 510 formed in the fourth and fifth substrates 400 and 500, respectively, may be connected by the first via holes V1 to configure the first coil C1 enclosing the magnetic core unit 110 in a solenoid form.

Here, the first and second coils C1 and C2 may be disposed to be perpendicular to one another.

A third coil C3 may be formed in at least one of the first to fifth substrates 100 and 500 to surround the magnetic core unit 110 and the first and second coils C1 and C2.

In detail, the third coil C3 may surround the first magnetic core unit 110 and the first and second coils C1 and C2 on a plane (x-y plane) in which the magnetic core unit 110 is formed.

Also, the third coil C3 may surround the magnetic core unit 110 and the first and second coils C1 and C2 on the x-y plane at least once in a spiral manner.

In the present exemplary embodiment, the third coil C3 is illustrated as being formed in the fifth substrate 500, but the present disclosure is not limited thereto and the third coil C3 may only need to be formed in any one of the first to fifth substrates 100 to 500.

Also, in order to improve sensitivity of the sensor, the third coil C3 may be formed in at least two substrates among the first to fifth substrates 100 to 500 in a solenoid form in the height direction (z-axis direction).

The first, second, and third coils C1, C2, and C3 may be magnetic field generating coils generating a magnetic field to magnetize the magnetic core unit 110 upon receiving an alternating current (AC) applied thereto, or may be detecting coils measuring an induction voltage according to a change in magnetic moment of the magnetic core unit 110 caused by an external magnetic field.

Namely, in the orthogonal fluxgate sensor according to the third exemplary embodiment, when at least one of the first and second coils C1 and C2 serves as a magnetic field generating coil, the third coil C3 may serve as a detecting coil, and when the third coil C3 serves as a magnetic field generating coil, at least one of the first and second coils C1 and C2 may serve as a detecting coil.

To this end, in a case in which an AC power source is connected to at least one of the first and second coils C1 and C2, an AC voltmeter may be connected to the third coil C3, and in a case in which the AC power source is connected to the third coil C3, the AC voltmeter may be connected to at least one of the first and second coils C1 and C2.

Thus, the first to third coils C1 to C3 may alternately serve to generate a magnetic field and detect a change in magnetic flux.

For example, in a case in which AC is applied to at least one of the first and second coils C1 and C2 to generate a magnetic field, a voltage induced to the third coil C3 due to a change in magnetic moment of the magnetic core unit 110 may be measured, and in a case in which AC is applied to the third coil C3 to generate a magnetic field, a voltage induced to at least one of the first and second coils C1 and C2 due to a change in magnetic moment of the magnetic core unit 110 may be measured.

The orthogonal fluxgate sensor according to the third exemplary embodiment of the present disclosure may operate as follows.

A method of measuring an external magnetic field (geo-magnetic field) in the z-axis direction will be described with reference to FIG. 4A.

When an external magnetic field in the z-axis direction is applied, the first magnetic core unit 111 has magnetic moment proportional to the external magnetic field in the z-axis direction.

Here, a current is applied to the first coil C1 to apply a magnetic field in the x-axis direction to the first magnetic core unit 111.

Namely, in the orthogonal fluxgate sensor according to the third exemplary embodiment of the present disclosure, the direction (here, the z-axis direction) of the external magnetic field intended to be measured and the direction (here, the x-axis direction) of the magnetic field generated by the magnetic field generating coil (here, the first coil C1) to magnetize the first magnetic core unit 111 form a right angle.

The current applied to the first coil C1 is an AC, so the direction of the magnetic field thereof is repeatedly changing between a positive (+) direction and a negative (−) direction of the x axis.

When an instantaneous current value of the AC applied to the first coil C1 is 0, the magnetic moment of the first magnetic core unit 111 is maintained at the initial value (with its component only along the z-axis).

When the instantaneous current value of the AC applied to the first coil C1 has a maximum positive value, the magnetic moment of the first magnetic core unit 111 is saturated to the x-axis direction, and thus, the initial component along the z-axis is rapidly reduced.

Here, the component along the z-axis of the magnetic moment of the first magnetic core unit 111 is changed, and a change in magnetic flux corresponding thereto may be sensed by the third coil C3.

Each time the instantaneous current value of the AC applied to the first coil C1 is changing between 0 and the maximum value thereof, the magnetic moment of the first magnetic core unit 111 in the z-axis direction is changed and may be measured by the voltage induced to the third coil C3.

The measured voltage of the third coil C3 is proportional to the magnitude of the external magnetic field in the z-axis direction.

Namely, the external magnetic field in the z-axis direction may be detected by measuring the voltage induced to the third coil C3.

Here, the first coil C1 to which the AC power source is connected may serve as a magnetic field generating coil, and the third coil C3 connected to the AC voltmeter may serve as a detecting coil.

Meanwhile, when the external magnetic field (geo-magnetic field) in the z-axis direction is measured, the second coil C2 may serve as a magnetic field generating coil.

For example, the voltage induced to the third coil C3 may also be measured by applying an AC to the second coil C2 to generate a magnetic field in the y-axis direction, thus saturating the magnetic moment of the second magnetic core unit 112 in the y-axis direction.

In this case, the second coil C2 to which the AC power source is connected may serve as a magnetic field generating coil and the third coil C3 connected to the AC voltmeter may serve as a detecting coil.

Also, after an AC is simultaneously applied to both the first coil C1 and the second coil C2, the external magnetic field (geo-magnetic field) in the z-axis direction may be measured by using both the first and second magnetic core units 111 and 112.

Thus, in measuring the external magnetic field (geo-magnetic field) in the z-axis direction, at least one of the first and second coils C1 and C2 may serve as a magnetic field generating coil and the third coil C3 may serve as a detecting coil.

To this end, the AC power source may be connected to at least one of the first and second coils C1 and C2, and the third coil C3 may be connected to the AC voltmeter.

Hereinafter, a method of measuring an external magnetic field (geo-magnetic field) in the x-axis direction will be described.

When an external magnetic field in the x-axis direction is applied, the first magnetic core unit 111 has magnetic moment proportional to the external magnetic field in the x-axis direction.

Here, a current is applied to the third coil C3 to apply a magnetic field in the z-axis direction to the first magnetic core unit 111.

Namely, in the orthogonal fluxgate sensor according to the third exemplary embodiment of the present disclosure, the direction (here, the x-axis direction) of the external magnetic field intended to be measured and the direction (here, the z-axis direction) of the magnetic field generated by the magnetic field generating coil (here, the third coil C3) to magnetize the first magnetic core unit 111 form a right angle.

The current applied to the third coil C3 is an AC, so the direction of the magnetic field thereof is repeatedly changing between a positive (+) direction and a negative (−) direction of the z axis.

When an instantaneous current value of the AC applied to the third coil C3 is 0, the magnetic moment of the first magnetic core unit 111 is maintained at the initial value (with its component only along the x-axis).

When the instantaneous current value of the AC applied to the third coil C3 has a maximum positive value, the magnetic moment of the first magnetic core unit 111 is saturated to the z-axis direction, and thus, the initial component along the z-axis is rapidly reduced.

Here, the component along the x-axis of the magnetic moment of the first magnetic core unit 111 is changed, and a change in magnetic flux corresponding thereto may be sensed by the first coil C1.

Each time the instantaneous current value of the AC applied to the third coil C3 is changing between 0 and the maximum value thereof, the magnetic moment of the first magnetic core unit 111 in the x-axis direction is changed and may be measured by the voltage induced to the first coil C1.

The measured voltage of the first coil C1 is proportional to the magnitude of the external magnetic field in the x-axis direction.

Namely, the external magnetic field in the x-axis direction may be detected by measuring the voltage induced to the first coil C1.

Here, the third coil C3 to which the AC power source is connected may serve as a magnetic field generating coil, and the first coil C1 connected to the AC voltmeter may serve as a detecting coil.

Hereinafter, a method of measuring an external magnetic field (geo-magnetic field) in the y-axis direction will be described.

When an external magnetic field in the y-axis direction is applied, the second magnetic core unit 112 has magnetic moment proportional to the external magnetic field in the y-axis direction.

Here, a current is applied to the third coil C3 to apply a magnetic field in the z-axis direction to the second magnetic core unit 112.

Namely, in the orthogonal fluxgate sensor according to the third exemplary embodiment of the present disclosure, the direction (here, the y-axis direction) of the external magnetic field intended to be measured and the direction (here, the z-axis direction) of the magnetic field generated by the magnetic field generating coil (here, the third coil C3) to magnetize the second magnetic core unit 112 form a right angle.

The current applied to the third coil C3 is an AC, so the direction of the magnetic field thereof is repeatedly changing between a positive (+) direction and a negative (−) direction of the z axis.

When an instantaneous current value of the AC applied to the third coil C3 is 0, the magnetic moment of the second magnetic core unit 112 is maintained at the initial value (with its component only along the y-axis).

When the instantaneous current value of the AC applied to the third coil C3 has a maximum positive value, the magnetic moment of the second magnetic core unit 112 is saturated to the z-axis direction, and thus, the initial component along the y-axis is rapidly reduced.

Here, the component along the y-axis of the magnetic moment of the second magnetic core unit 112 is changed, and a change in magnetic flux corresponding thereto may be sensed by the second coil C2.

Each time the instantaneous current value of the AC applied to the first coil C1 is changing between 0 and the maximum value thereof, the magnetic moment of the second magnetic core unit 112 in the y-axis direction is changed and may be measured by the voltage induced to the second coil C2.

The measured voltage of the second coil C2 is proportional to the magnitude of the external magnetic field in the y-axis direction.

Namely, the external magnetic field in the y-axis direction may be detected by measuring the voltage induced to the second coil C2.

Here, the third coil C3 to which the AC power source is connected may serve as a magnetic field generating coil, and the second coil C2 connected to the AC voltmeter may serve as a detecting coil.

In the orthogonal fluxgate sensor according to the third exemplary embodiment of the present disclosure, the first to third coils C1 to C3 may alternately serve as a magnetic field generating coil and a detecting coil, eliminating the need for a separate magnetic field generating coil and detecting coil, and thus, the overall size of the sensor may be reduced.

Also, since the first and second magnetic thin films 111a and 112a formed on the inner walls of the first and second through holes 120 and 130 have a width smaller than a length and a height thereof, demagnetizing field of the magnetic core units 110 with respect to the magnetic fields in the length direction (the x-axis direction or the y-axis direction) and the height direction (the z-axis direction or the direction perpendicular to the x-y plane) may be reduced, improving sensitivity and efficiency of the sensor.

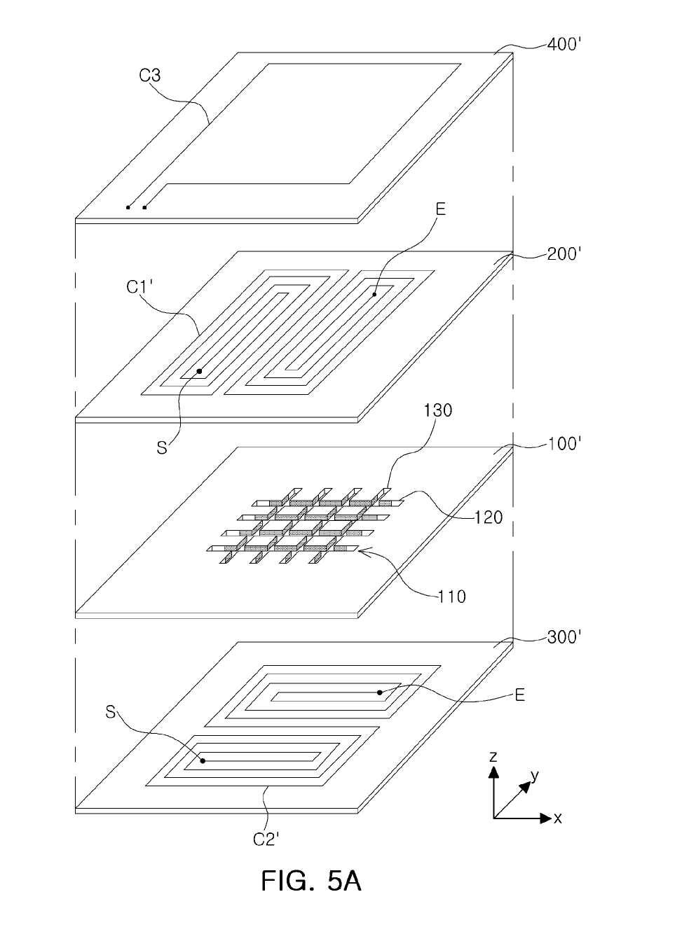

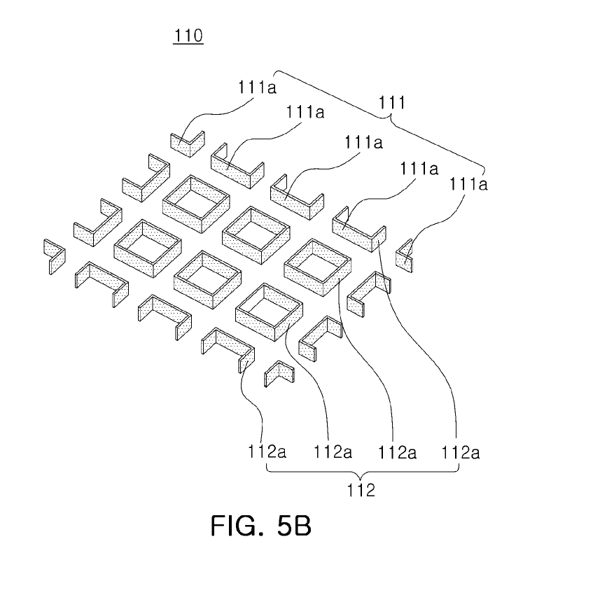

FIG. 5A is an exploded perspective view schematically illustrating an orthogonal fluxgate sensor according to a fourth exemplary embodiment of the present disclosure, and FIG. 5B is a perspective view of a magnetic core unit provided in the orthogonal fluxgate sensor according to the fourth exemplary embodiment of the present disclosure.

Referring to FIGS. 5A and 5B, the orthogonal fluxgate sensor according to the fourth exemplary embodiment of the present disclosure is identical to the orthogonal fluxgate sensor according to the third exemplary embodiment of the present disclosure as described above, except for first and second coils C1′ and C2′, so descriptions thereof, excluding those of the first and second coils C1′ and C2′, will be omitted.

The orthogonal fluxgate sensor according to the fourth exemplary embodiment of the present disclosure may include a first substrate 100′ in which a magnetic core unit 110 is formed, and second, third, and fourth, substrates 200′, 300′, and 400′ in which conductive patterns are formed.

The second and third substrates 200′ and 300′ may be respectively stacked above and below the first substrate 100′ with the first substrate 100′ as a center, forming a multi-layer substrate.

The second substrate 200′ may be stacked on the first substrate 100′, and the third substrate 300′ may be stacked below the first substrate 100′.

Conductive patterns may be formed on the second and third substrate 200′ and 300′.

For example, a first coil C1′ may be patterned to have a spiral shape on the second substrate 200′ such that the parts of the first coil C1′ directly above the magnetic core unit 110 form parallel lines, and a second coil C2′ may be patterned to have a spiral shape on the third substrate 300′ such that the parts of the second coil C2′ directly below the magnetic core unit 110 form parallel lines.

The first coil C1′ may be formed by connecting the outermost coil strands of two coils wound in the same direction.

Also, the first coil C1′ may be formed to spread, while being wound in one direction, and be rewound in the opposite direction.

In other words, the first coil C1′ may have a dual-spiral structure.

Also, the second coil C2′ may have a shape identical to that of the first coil C1′, but the first and second coils C1′ and C2′ may be disposed to be perpendicular to one another.

When it is assumed that a current flows from a start point S to an end point E of the first coil C1′, the current flows in the same direction in an inner portion of the first coil C1′.

Here, the magnetic core unit 110 may be positioned within the region of the first coil C1′ in which the current flows in one direction and the region of the second coil C2′ in which the current flows in another direction.

Also, the magnetic core unit 110 may be positioned between the start points S and the end points E of the first and second coils C1′ and C2′.

Thus, a magnetic field may be applied to the entirety of the magnetic core unit 110 in a predetermined direction by the first and second coils C1′ and C2′.

In the present exemplary embodiment, the magnetic core unit 110 is disposed between the first and second coils C1′ and C2′, but the present disclosure is not limited thereto and the magnetic core unit 110 may be positioned above or below the first and second coils C1′ and C2.

For example, the first substrate 100′ with the magnetic core unit 110 formed therein, the second substrate 200′ with the first coil C1′ formed therein, and the third substrate 300′ with the second coil C2′ formed therein may be stacked in order, or may be stacked in reverse order.

This is because an operation or sensitivity of the sensor is not affected by stacking order as long as the magnetic core unit 110 is in proximity of the first and second coils C1′ and C2′.

Meanwhile, the fourth substrate 400′ may be stacked on the second substrate 200′ or below the fourth substrate 400′.

A conductive pattern may be formed in the fourth substrate 400′ to constitute the third coil C3.

The third coil C3 may be provided to surround the magnetic core unit 110 and the first and second coils C1 and C2.

In detail, the third coil C3 may surround the first magnetic core unit 110 and the first and second coils C1 and C2 on a plane (x-y plane) in which the magnetic core unit 110 is formed.

Also, the third coil C3 may surround the magnetic core unit 110 and the first and second coils C1 and C2 on the x-y plane at least once in a spiral manner.

In the present exemplary embodiment, the fourth substrate 400′ is stacked on the second substrate 200′ and the third coil C3 is formed in the fourth substrate 400′, but the present disclosure is not limited thereto and the fourth coil 400′ with the third coil C3 formed therein may be stacked below the third substrate 300′ and the third coil C3 may be formed in at least one of the first to third substrates 100′ to 300′. In this case, the fourth substrate 400′ may not be necessary.

The orthogonal fluxgate sensor according to the fourth exemplary embodiment of the present disclosure may operate in the same manner as the orthogonal fluxgate sensor according to the third exemplary embodiment of the present disclosure.

For example, in case of measuring an external magnetic field (geo-magnetic field) in the z-axis direction, magnetic moment of the first magnetic core unit 111 may be saturated in the x-axis direction by generating a magnetic field in the x-axis direction by applying an AC to the first coil C1′. Here, an external magnetic field in the z-axis direction may be detected by measuring a voltage induced to the third coil C3.

Also, magnetic moment of the first magnetic core unit 111 may be saturated in the y-axis direction by generating a magnetic field in the y-axis direction by applying an AC to the second coil C2′. Here, an external magnetic field in the z-axis direction may be detected by measuring a voltage induced to the third coil C3.

Meanwhile, after an AC is simultaneously applied to both the first and second coils C1′ and C2′, the external magnetic field (geo-magnetic field) may be measured by using both the first and second magnetic core units 111 and 112.

Thus, in measuring the external magnetic field (geo-magnetic field) in the z-axis direction, at least one of the first and second coils C1′ and C2′ may serve as a magnetic field generating coil and the third coil C3′ may serve as a detecting coil.

The foregoing descriptions of the orthogonal fluxgate sensor according to the third exemplary embodiment of the present disclosure will be used for the method of measuring the external magnetic fields (geo-magnetic fields) in the x-axis and y-axis directions.

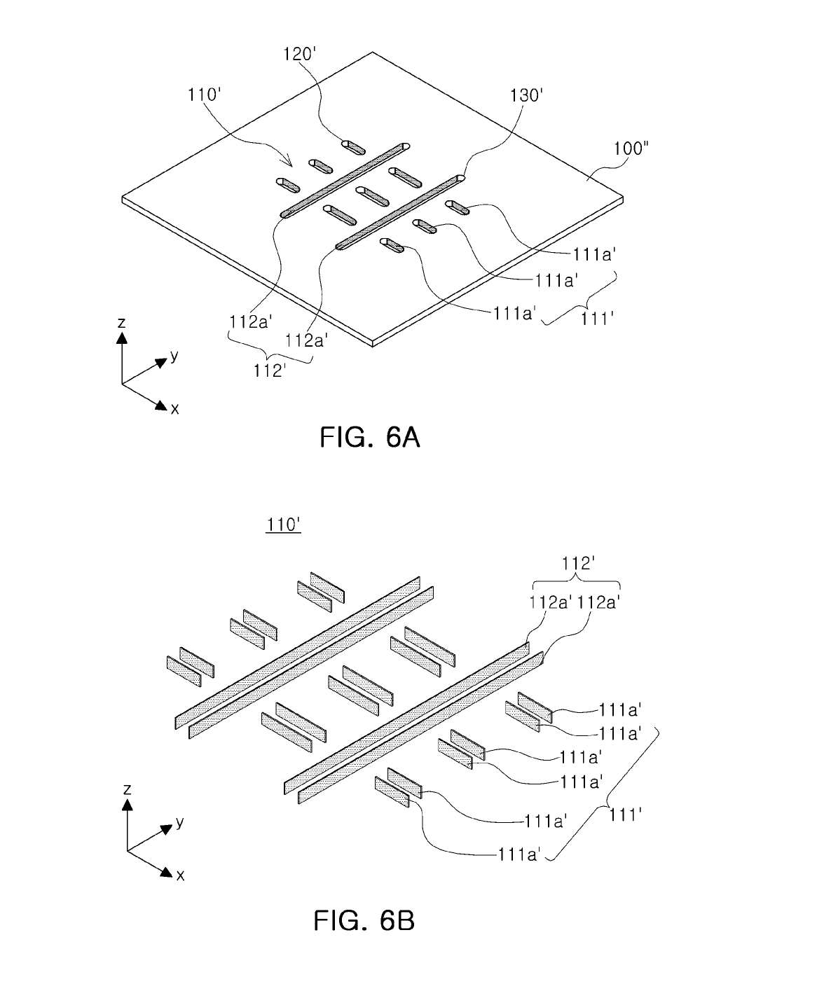

FIG. 6A is a perspective view of modified examples of a first substrate and the magnetic core unit provided in the orthogonal fluxgate sensors according to the third and fourth exemplary embodiments of the present disclosure, and FIG. 6B is a perspective view of a modified example of the magnetic core unit provided in the orthogonal fluxgate sensors according to the third and fourth exemplary embodiments of the present disclosure.

Modified examples of the first substrate and the magnetic core unit provided in the orthogonal fluxgate sensors according to the third and fourth exemplary embodiments of the present disclosure will be described with reference to FIGS. 6A and 6B.

The magnetic core unit 110′ may be formed in a first substrate 100″.

A plurality of first through holes 120′ having a rectangular shape and penetrating through a first substrate 100″ may be formed in the first substrate 100″. Each of the first through holes 120′ may be parallel to one another in the width direction (y-axis direction) thereof.

The first through holes 120′ may each be elongated in the length direction (x-axis direction) thereof, and may be formed to be spaced apart from one another by a predetermined distance in the length direction (x-axis direction) thereof.

A plurality of second through holes 130′ may be formed to be perpendicular to the plurality of first through holes 120′ in the first substrate 100″, and the respective second through holes 130′ may be parallel to one another in the width direction (x-axis direction) thereof.

The second through holes 120′ may each be elongated in the length direction (y-axis direction) thereof, and may be formed to be spaced apart from one another by a predetermined distance in the width direction (x-axis direction) thereof.

Each of the second through holes 130′ may be disposed between the plurality of first through holes 120′ formed to be spaced apart from one another in the length direction (x-axis direction) of the first through holes 120′.

A plurality of first and second magnetic thin films 111a′ and 112a′ may be provided on inner walls of the first and second through holes 120′ and 130′, forming the magnetic core unit 110′.

For example, a first magnetic core unit 111′ may be formed by the plurality of first magnetic thin films 111a′ provided on the inner walls of the first through holes 120′, and a second magnetic core unit 112′ may be formed by the plurality of second magnetic thin films 112a′ provided on the inner walls of the second through holes 130′.

The magnetic core unit 110′ may be formed by depositing the first and second magnetic thin films 111a′ and 112a′ on the inner walls of the first and second through holes 120′ and 130′ by using a thin film deposition method such as physical vapor deposition, chemical deposition, electro-deposition, and the like.

The magnetic core unit 110′ may be a soft magnet having small residual magnetization and high permeability, and may be formed of spinel-type ferrite, an amorphous alloy, and the like.

The magnetic core unit 110′ may be magnetized when an external magnetic field is applied thereto, and demagnetized when the applied external magnetic field is removed.

Each of the first and second magnetic thin films 111a′ and 112a′ may have a narrow, elongated bar shape erected vertically.

For example, each of the first magnetic thin films 111a′ constituting the first magnetic core unit 111′ may be formed to be narrower in a width direction (y-axis direction) thereof than in a length direction (x-axis direction) and a height direction (z-axis direction) thereof.

Thus, each of the first magnetic thin films 111a′ constituting the first magnetic core unit 111′ may have lower demagnetizing field over magnetic fields in the length direction (x-axis direction) and the height direction (z-axis direction) than those over the magnetic field in the width direction (y-axis direction).

Each of the first magnetic thin films 111a′ constituting the first magnetic core unit 111′ may be readily magnetized by the magnetic field in the x-axis direction induced by the first coil C1 or C1′ and the magnetic field in the z-axis direction inducted by the third coil C3.

Meanwhile, each of the second magnetic thin films 112a′ constituting the second magnetic core unit 112′ may be formed to be narrower in the width direction (x-axis direction) thereof than in the length direction (y-axis direction) and the height direction (z-axis direction) thereof.

Thus, each of the second magnetic thin films 112a′ constituting the second magnetic core unit 112′ may have lower demagnetizing field over magnetic fields in the length direction (y-axis direction) and the height direction (z-axis direction) than those over the magnetic field in the width direction (x-axis direction).

Each of the second magnetic thin films 112a′ constituting the second magnetic core unit 112′ may be readily magnetized by the magnetic field in the y-axis direction induced by the second coil C2 or C2′ and the magnetic field in the z-axis direction inducted by the third coil C3.

As set forth above, the orthogonal fluxgate sensor according to exemplary embodiments of the present disclosure may have an overall significantly reduced size, while measuring magnetic fields in 3-axis directions.

Also, since three coils alternately serve as a magnetic field generating coil and a detecting coil, the orthogonal fluxgate sensor may have a simpler structure and be miniaturized.

While exemplary embodiments have been shown and described above, it will be apparent to those skilled in the art that modifications and variations could be made without departing from the spirit and scope of the present disclosure as defined by the appended claims.

What is claimed is:

1. An orthogonal fluxgate sensor, comprising:
a magnetic core unit having a lattice structure;
first and second coils enclosing the magnetic core unit in a solenoid form; and
a third coil surrounding the magnetic core unit and the first and second coils,
wherein the first and second coils are disposed to be perpendicular to one another, and when an alternating current (AC) power source is connected to at least one of the first and second coils, an AC voltmeter is connected to the third coil, and when the AC power source is connected to the third coil, the AC voltmeter is connected to at least one of the first and second coils.

2. The orthogonal fluxgate sensor of claim 1, wherein the magnetic core unit is formed by disposing a plurality of bar-shaped magnetic cores to intersect each other.

3. The orthogonal fluxgate sensor of claim 1, wherein the magnetic core unit comprises a first magnetic core unit including a plurality of first bar-shaped magnetic cores disposed to be parallel to one another and a second magnetic core unit including a plurality of second bar-shaped magnetic cores disposed to be parallel to one another, and the first and second magnetic core units are disposed to be perpendicular to one another.

4. The orthogonal fluxgate sensor of claim 3, wherein each of the first magnetic cores provided in the first magnetic core unit is formed to be narrow in a width direction thereof, relative to length and height directions thereof, and each of the second magnetic cores provided in the second magnetic core unit is formed to be narrow in a width direction thereof, relative to length and height directions thereof.

5. The orthogonal fluxgate sensor of claim 3, wherein each of the first and second magnetic cores has lower demagnetizing field over magnetic fields in the length and height directions thereof than those over a magnetic field in the width direction thereof.

6. The orthogonal fluxgate sensor of claim 1, wherein the third coil surrounds the magnetic core unit and the first and second coils at least once in a spiral manner.

7. An orthogonal fluxgate sensor, comprising:
a magnetic core unit having a lattice structure;
a first coil disposed above the magnetic core unit and having a spiral shape with the parts of the first coil directly above the magnetic cores forming parallel lines;
a second coil disposed below the magnetic core unit and having a spiral shape with the parts of the second coil directly below the magnetic cores forming parallel lines; and
a third coil surrounding the magnetic core unit and the first and second coils,
wherein the first and second coils are disposed to be perpendicular to one another, and when an alternating current (AC) power source is connected to at least one of the first and second coils, an AC voltmeter is connected to the third coil, and when an AC power source is connected to the third coil, the AC voltmeter is connected to at least one of the first and second coils.

8. The orthogonal fluxgate sensor of claim 7, wherein the magnetic core unit is formed by disposing a plurality of bar-shaped magnetic cores such that they intersect.

9. The orthogonal fluxgate sensor of claim 7, wherein the magnetic core unit comprises a first magnetic core unit including a plurality of first bar-shaped magnetic cores disposed to be parallel to one another and a second magnetic core unit including a plurality of second bar-shaped magnetic cores disposed to be parallel to one another, and the first and second magnetic core units are disposed to be perpendicular to one another.

10. The orthogonal fluxgate sensor of claim 9, wherein each of the first magnetic cores provided in the first magnetic core unit is formed to be narrow in a width direction thereof, relative to length and height directions thereof, and each of the second magnetic cores provided in the second magnetic core unit is formed to be narrow in a width direction thereof, relative to length and height directions thereof.

11. The orthogonal fluxgate sensor of claim 9, wherein each of the first and second magnetic cores has lower demagnetizing field over magnetic fields in the length and height directions thereof than those over a magnetic field in the width direction thereof.

12. The orthogonal fluxgate sensor of claim 7, wherein the magnetic core unit is positioned within a region of the first coil in which a current flows in one direction and within a region of the second coil in which a current flows in another direction.

13. An orthogonal fluxgate sensor, comprising:
a first substrate including a magnetic core unit having a lattice structure formed therein;
second and third substrates stacked above and below the first substrate, respectively, and having a second coil surrounding the magnetic core unit in a solenoid form; and
fourth and fifth substrates stacked above the second substrate and below the third substrate, respectively, and having a first coil surrounding the magnetic core unit in a solenoid form,
wherein the first and second coils are perpendicular to one another, a third coil is formed to surround the magnetic core unit and the first and second coils in at least one of the first to fifth substrates, and when an alternating current (AC) power source is connected to at least one of the first and second coils, an AC voltmeter is connected to the third coil, and when the AC power source is connected to the third coil, the AC voltmeter is connected to at least one of the first and second coils.

14. The orthogonal fluxgate sensor of claim 13, wherein the first substrate comprises a plurality of first through holes and a plurality of second through holes penetrating therethrough in a rectangular shape, the plurality of first through holes and the plurality of second through holes are perpendicular to one another, and a plurality of first and second magnetic thin films are provided on inner walls of the first and second through holes to form the magnetic core unit.

15. The orthogonal fluxgate sensor of claim 13, wherein the first and second magnetic thin films provided on the inner walls of the first and second through holes have lower demagnetizing field over magnetic fields in length and height directions than those over a magnetic field in a width direction thereof.

16. The orthogonal fluxgate sensor of claim 13, wherein the second and third substrates have conductive patterns formed therein, and the first through third substrates have second via holes to allow end portions of the respective conductive patters to be connected therethrough to form the second coil in a solenoid form.

17. The orthogonal fluxgate sensor of claim 13, wherein the fourth and fifth substrates have conductive patterns formed therein, and the first through fifth substrates have first via holes to allow end portions of the respective conductive patters to be connected therethrough to form the first coil in a solenoid form.

18. An orthogonal fluxgate sensor, comprising:
a first substrate including a magnetic core unit having a lattice structure formed therein;
a second substrate stacked above the first substrate and having a first coil patterned in a spiral shape such that the parts of the first coil directly above the magnetic cores form parallel lines;
a third substrate stacked below the first substrate and having a second coil patterned in a spiral shape such that the parts of the second coil directly below the magnetic cores form parallel lines; and
a fourth substrate stacked above the second substrate or below the third substrate and having a third coil patterned to surround the first and second coils,
wherein the first and second coils are perpendicular to one another, and when an alternating current (AC) power source is connected to at least one of the first and second coils, an AC voltmeter is connected to the third coil, and when an AC power source is applied to the third coil, the AC voltmeter is connected to at least one of the first and second coils.

19. The orthogonal fluxgate sensor of claim 18, wherein the first substrate comprises a plurality of first through holes and a plurality of second through holes penetrating therethrough in a rectangular shape, the plurality of first through holes and the plurality of second through holes are perpendicular to one another, and a plurality of first and second magnetic thin films are provided on inner walls of the first and second through holes to form the magnetic core unit.

20. The orthogonal fluxgate sensor of claim 19, wherein the first and second magnetic thin films provided on the inner walls of the first and second through holes have lower demagnetizing field over magnetic fields in length and height directions than those over a magnetic field in a width direction thereof.
